(19) United States
(12) Patent Application Publication
(10) Pub. No.: US 2025/0323670 A1
(43) Pub. Date: Oct. 16, 2025

(54) Electronic device, communication chip, and transmitter power ramping control thereof

(71) Applicant: REALTEK SEMICONDUCTOR CORPORATION, HSINCHU (TW)

(72) Inventor: YI-CHANG SHIH, Hsinchu (TW)

(21) Appl. No.: 19/090,725

(22) Filed: Mar. 26, 2025

(30) Foreign Application Priority Data
Apr. 11, 2024 (TW) 113113621

(51) Int. Cl. H04B 1/04; H03F 3/24; H04B 1/40

(52) U.S. Cl. CPC H04B 1/04; H03F 3/245; H04B 1/40; H03F 2200/451

(57) ABSTRACT

A communication chip includes a digital baseband circuit, a reference signal generation circuit, a power amplifier driver (PAD), a power amplifier (PA), and a digital-to-analog converter (DAC). The digital baseband circuit is used to generate a control signal and a control code. The reference signal generation circuit is coupled to the digital baseband circuit and is used to generate a reference signal and change the frequency of the reference signal according to the control signal. The PAD is coupled to the reference signal generation circuit. The PA is coupled to the PAD. The DAC is coupled to the digital baseband circuit and is used to control the output power of at least one of the PAD and the PA according to the control code. The PAD and the PA amplify the reference signal. The control signal is not equal to the control code.

### BACKGROUND OF THE INVENTION

### 1. Field of the Invention

The present invention generally relates to an electronic device, and, more particularly, to an electronic device implementing the transmitter power ramping control and a communication chip thereof.

### 2. Description of Related Art

A radio frequency (RF) transmitter circuit must handle the RF power ramp-up when turning on (starting to transmit signals) and the RF power ramp-down when turning off (ending the transmission of signals), collectively referred to as the transmitter power ramping.

The RF transmitter circuit typically includes a power amplifier (PA) and a power amplifier driver (PAD). FIG. 1 shows the circuit used for performing the transmitter power ramping in a PAD. The circuit of FIG. 1 mainly includes a current source 110, a transistor M1, and a low-pass filter (LPF) 120. The LPF 120 includes a resistor R1 and a capacitor C1. The voltage PA_bias is used for biasing the PA. The disadvantage of the circuit in FIG. 1 is that the adjustable parameters are too few, making the transmitter power ramping lack flexibility, resulting in the RF power of the electronic device failing to meet the regulations in certain situations.

### SUMMARY OF THE INVENTION

In view of the issues of the prior art, an object of the present invention is to provide an electronic device and its communication chip, so as to make an improvement to the prior art.

According to one aspect of the present invention, a communication chip is provided. The communication chip includes a digital baseband circuit, a reference signal generation circuit, a power amplifier driver (PAD), a power amplifier (PA), and a digital-to-analog converter (DAC). The digital baseband circuit is used to generate a control signal and a control code. The reference signal generation circuit is coupled to the digital baseband circuit and is used to generate a reference signal and change the frequency of the reference signal according to the control signal. The PAD is coupled to the reference signal generation circuit. The PA is coupled to the PAD. The DAC is coupled to the digital baseband circuit and is used to control the output power of at least one of the PAD and the PA according to the control code. The PAD and the PA amplify the reference signal, and the control signal is not equal to the control code.

According to another aspect of the present invention, an electronic device is provided. The electronic device is used to transmit a radio frequency output signal or receive a radio frequency input signal. The electronic device includes an antenna and a communication chip. The communication chip includes a digital baseband circuit, a reference signal generation circuit, a PAD, a PA, and a DAC. The digital baseband circuit is used to generate a control signal and a control code. The reference signal generation circuit is coupled to the digital baseband circuit and is used to generate a reference signal and change the frequency of the reference signal according to the control signal. The PAD is coupled to the reference signal generation circuit. The PA is coupled to the PAD. The DAC is coupled to the digital baseband circuit and is used to control the output power of at least one of the PAD and the PA according to the control code. The PAD and the PA amplify the reference signal, and the control signal is not equal to the control code.

The technical means embodied in the embodiments of the present invention can solve at least one of the problems of the prior art. Therefore, compared to the prior art, the present invention can enhance the flexibility of the transmitter power ramping.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows the circuit used for transmitter power ramping in a power amplifier driver (PAD).

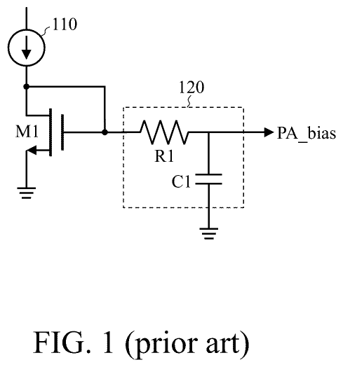

FIG. 2 is the functional block diagram of the electronic device according to an embodiment of the present invention.

FIG. 3 is the detailed functional block diagram of the communication chip according to an embodiment of the present invention.

FIG. 4 shows an embodiment of the connections among the impedance matching circuit, the PAD, and the power amplifier (PA) of FIG. 3.

FIG. 5 is a functional block diagram of the transmitter power ramping of the communication chip in the two-point modulation (TPM) mode according to an embodiment of the present invention.

FIG. 6 is a circuit diagram of the PAD and the PA according to an embodiment of the present invention.

FIG. 7 is a schematic diagram of the control code for the radio frequency (RF) power ramp-up control according to an embodiment of the present invention.

FIG. 8 is a schematic diagram of the control code for the RF power ramp-down control according to an embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an electronic device and its communication chip. On account of that some or all elements of the electronic device and the communication chip could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

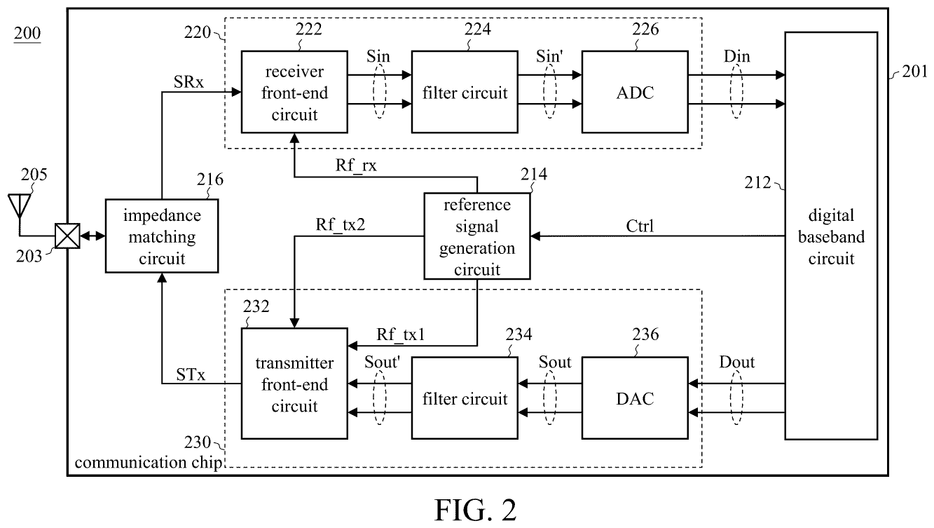

Reference is made to FIG. 2, which is a functional block diagram of the electronic device according to an embodiment of the present invention. The electronic device 200 includes a communication chip 201 and an antenna 205. The communication chip 201 includes a pin 203, a digital baseband circuit 212, a reference signal generation circuit 214, an impedance matching circuit 216, a receiver circuit 220, and a transmitter circuit 230. The receiver circuit 220 includes a receiver front-end circuit 222, a filter circuit 224, and an analog-to-digital converter (ADC) 226. The transmitter circuit 230 includes a transmitter front-end circuit 232, a filter circuit 234, and a digital-to-analog converter (DAC) 236. The impedance matching circuit 216 is used for implementing the impedance matching of the transmission line. The filter circuit 224 and the filter circuit 234 may be a complex filter or a low-pass filter (LPF). The communication chip 201 is coupled to the antenna 205 through the pin 203.

The digital baseband circuit 212 is coupled or electrically connected to the reference signal generation circuit 214, the receiver circuit 220, and the transmitter circuit 230. For the transmitter circuit 230 (more specifically, for the transmitter front- end circuit 232), the reference signal generation circuit 214 generates a reference signal Rf_tx1 in the in-phase quadrature modulation (IQM) mode, and generates a reference signal Rf_tx2 in the two-point modulation (TPM) mode. For the receiver circuit 220 (more specifically, for the receiver front-end circuit 222), the reference signal generation circuit 214 generates a reference signal Rf_rx in both the IQM mode and the TPM mode, and the frequency of the reference signal Rf_rx in the IQM mode can be equal to or not equal to the frequency in the TPM mode.

The digital baseband circuit 212 generates a control signal Ctrl and a control code D_ramp. The digital baseband circuit 212 uses the control signal Ctrl to control the reference signal generation circuit 214 to set or adjust (change) the frequency of the reference signal Rf_tx1 and/or the frequency of the reference signal Rf_tx2. In the IQM mode, the frequency of the reference signal Rf_tx1 is fixed (i.e., the reference signal Rf_tx1 is a single tone signal). In the TPM mode, the digital baseband circuit 212 performs frequency modulation (FM) on the reference signal Rf_tx2 through the control signal Ctrl (equivalent to performing frequency modulation on the radio frequency (RF) output signal STx).

In the IQM mode, the transmitter circuit 230 converts the digital output signal Dout generated by the digital baseband circuit 212 into the RF output signal STx. The RF output signal STx is coupled to the antenna 205 via the impedance matching circuit 216 and the pin 203. More specifically, the DAC 236 converts the digital output signal Dout into the analog output signal Sout. The filter circuit 234 filters the analog output signal Sout to generate the filtered analog output signal Sout′. The transmitter front-end circuit 232 up-converts and amplifies the filtered analog output signal Sout′ according to the reference signal Rf_tx1 to generate the RF output signal STx.

In the TPM mode, the filter circuit 234 and the DAC 236 are inactive, while the transmitter front-end circuit 232 amplifies the reference signal Rf_tx2 to generate the RF output signal STx. The RF output signal STx is coupled to the antenna 205 via the impedance matching circuit 216 and the pin 203.

The receiver circuit 220 converts the RF input signal SRx, which the communication chip 201 receives through the antenna 205 and the pin 203, into the digital input signal Din. More specifically, the receiver front-end circuit 222 down-converts the RF input signal SRx according to the reference signal Rf_rx to generate the analog input signal Sin. The filter circuit 224 filters the analog input signal Sin to generate the filtered analog input signal Sin′. The ADC 226 converts the filtered analog input signal Sin′ into the digital input signal Din.

Due to the shared use of the impedance matching circuit 216 by the receiver circuit 220 and the transmitter circuit 230, the communication chip 201 can transmit the RF output signal STx or receive the RF input signal SRx through the same pin (i.e., the pin 203). Furthermore, because the receiver circuit 220 and the transmitter circuit 230 share the pin 203, the antenna 205 does not need to switch between two pins. In other words, the pin 203 and the antenna 205 can be electrically connected to each other.

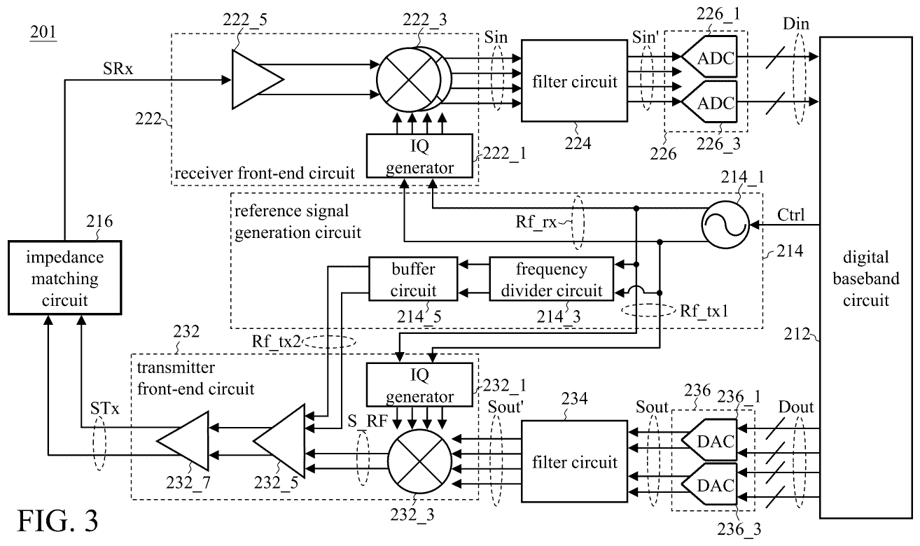

Reference is made to FIG. 3, which is a detailed functional block diagram of the communication chip 201 according to an embodiment of the present invention. The reference signal generation circuit 214 includes a synthesizer 214_1, a frequency divider circuit 214_3, and a buffer circuit 214_5. The receiver front-end circuit 222 includes an in-phase quadrature generator (IQ generator) 222_1, a mixer circuit 222_3, and a low noise amplifier (LNA) 222_5. The ADC 226 includes an ADC 226_1 and an ADC 226_3. The transmitter front-end circuit 232 includes an IQ generator 232_1, a mixer circuit 232_3, a power amplifier driver (PAD) 232_5, and a power amplifier (PA) 232_7. The DAC 236 includes a DAC 236_1 and a DAC 236_3. The IQM mode and the TPM mode are respectively discussed as follows.

### Mode (1): the IQM Mode.

The synthesizer 214_1 generates the reference signal Rf_tx1 with a fixed frequency (i.e., the reference signal Rf_tx1 is a single tone signal), and the frequency divider circuit 214_3 and the buffer circuit 214_5 are inactive or disabled (in other words, in the IQM mode, the reference signal Rf_tx2 does not exist). More specifically, the digital baseband circuit 212 sets the frequency of the reference signal Rf_tx1 with the control signal Ctrl, and then the synthesizer 214_1 operates at that frequency afterwards. Alternatively, the synthesizer 214_1 operates at a default frequency (i.e., the frequency of the reference signal Rf_tx1) without being controlled by the control signal Ctrl.

In some embodiments, the control signal Ctrl is a digital signal, and the synthesizer 214_1 is a digitally controlled synthesizer (e.g., including a digital controlled oscillator (DCO)).

When the communication chip 201 transmits a signal, the IQ generator 232_1 generates an in-phase signal and a quadrature signal based on the reference signal Rf_tx1, and the mixer circuit 232_3 up-converts the filtered analog output signal Sout′ based on the in-phase signal and the quadrature signal to generate the RF signal S_RF. The RF signal S_RF is amplified by the PAD 232_5 and the PA 232_7 to generate the RF output signal STx.

When the communication chip 201 receives a signal, the synthesizer 214_1 generates the reference signal Rf_rx, the IQ generator 222_1 generates an in- phase signal and a quadrature signal based on the reference signal Rf_rx, and the mixer circuit 222_3 down-converts the output signal of the LNA 222_5 based on the in-phase signal and the quadrature signal to generate the analog input signal Sin.

### Mode (2): The TPM Mode.

When the communication chip 201 transmits a signal, the digital baseband circuit 212 controls the synthesizer 214_1 with the control signal Ctrl to change the frequencies of the reference signal Rf_tx1 and the reference signal Rf_tx2, in order to achieve the purpose of frequency modulation of the RF output signal STx. The reference signal Rf_tx2 is the signal resulting from the processing of the reference signal Rf_tx1 by the frequency divider circuit 214_3 and the buffer circuit 214_5. The PAD 232_5 and the PA 232_7 amplify the reference signal Rf_tx2 to generate the RF output signal STx. The purpose of the frequency divider circuit 214_3 is to make the frequency of the RF output signal STx not equal to the frequency of the reference signal Rf_tx1, so as to prevent the large power of the RF output signal STx from affecting the operation of the synthesizer 214_1 when the RF output signal STx and the reference signal Rf_tx1 are at the same frequency. The purpose of the buffer circuit 214_5 is to enhance the power of the signal to counter the signal attenuation on the transmission line.

In some embodiments, if the power of the RF output signal STx is relatively small or the synthesizer 214_1 is relatively ideal, then the frequency divider circuit 214_3 can be omitted.

In some embodiments, if the signal attenuation on the transmission line is relatively small, the buffer circuit 214_5 can be omitted.

The operation of the receiver front-end circuit 222 in the TPM mode is the same as the operation in the IQM mode, so further elaboration is omitted for brevity. It should be noted that when the communication chip 201 receives a signal, whether in the IQM mode or TPM mode, the reference signal Rf_rx is a single tone signal. In other words, the digital baseband circuit 212 does not perform frequency modulation on the reference signal Rf_rx.

It can be known from above that, in the TPM mode, the digital baseband circuit 212 modulates the frequency of the reference signal Rf_tx1 (equivalent to modulating the frequency of the reference signal Rf_tx2 and the RF output signal STx) through the control signal Ctrl.

In some embodiments, since the IQ generator 232_1, the mixer circuit 232_3, the filter circuit 234, and the DAC 236 are inactive in the TPM mode, the digital baseband circuit 212 can turn off or disable these components to save power.

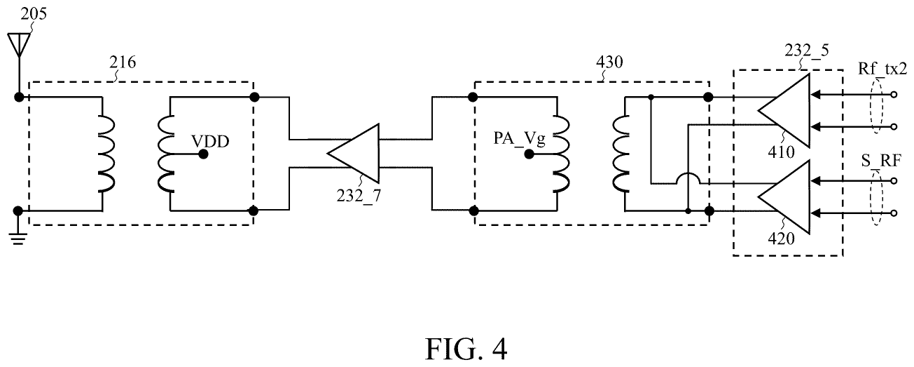

Reference is made to FIG. 4, which shows an embodiment of the connections among the impedance matching circuit 216, the PAD 232_5, and the PA 232_7 in FIG. 3. In the embodiment of FIG. 4, the impedance matching circuit 216 is a transformer, and the transmitter front-end circuit 232, in addition to including the PAD 232_5 and the PA 232_7, also includes a transformer 430. The PAD 232_5 includes a sub-PAD 410 and a sub-PAD 420, which are used to process (e.g., amplify) the reference signal Rf_tx2 and the RF signal S_RF, respectively. The primary side of the transformer 430 is coupled or electrically connected to the sub-PAD 410 and the sub-PAD 420, while the secondary side is coupled or electrically connected to the PA 232_7. The voltage PA_Vg is the gate bias of the main transistor of the PA 232_7. The primary side of the impedance matching circuit 216 is coupled or electrically connected to the PA 232_7, while the secondary side is coupled or electrically connected to the antenna 205. The voltage VDD is the power supply voltage of the PA 232_7.

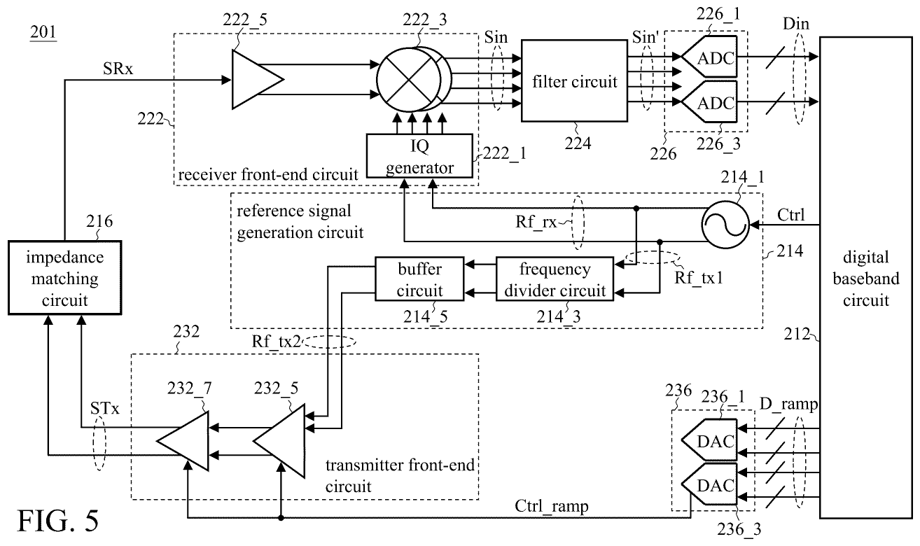

Reference is made to FIG. 5, which is a functional block diagram of the transmitter power ramping of the communication chip 201 in the TPM mode according to an embodiment of the present invention. As discussed above, because in the TPM mode, the filter circuit 234, the IQ generator 232_1, and the mixer circuit 232_3 are inactive and/or disabled, these components are omitted in FIG. 5. In the TPM mode, the DAC 236 is used for performing the transmitter power ramping. More specifically, the digital baseband circuit 212 generates the control code D_ramp used for performing the transmitter power ramping. The DAC 236 converts the control code D_ramp into a regulation signal Ctrl_ramp to control at least one of the PAD 232_5 and the PA 232_7 (e.g., controlling at least one output power of at least one of the PAD 232_5 and the PA 232_7). It should be noted that the control code D_ramp is not the control signal Ctrl.

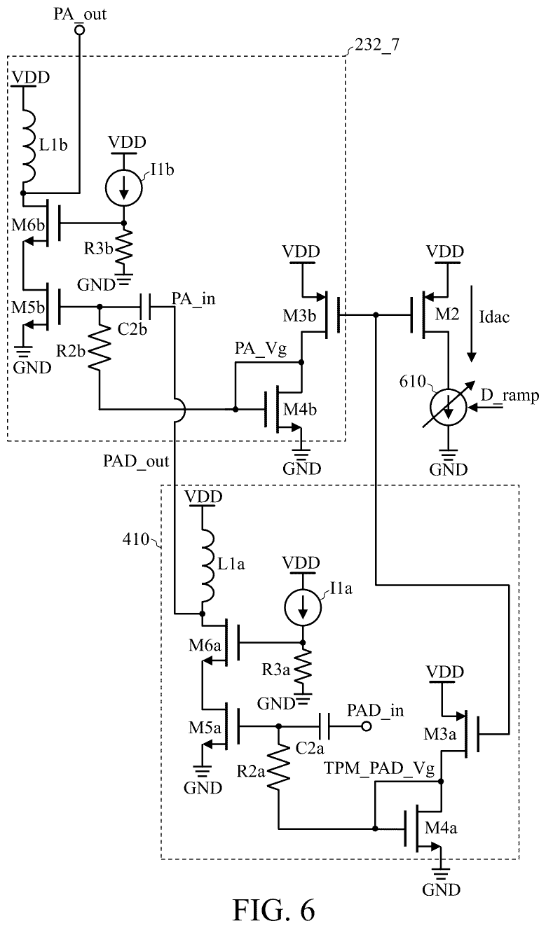

Reference is made to FIG. 6, which is a circuit diagram of a PAD and a PA according to an embodiment of the present invention. The sub-PAD 410 is similar to the PA 232_7. The sub-PAD 410 (the PA 232_7) includes a transistor M3a (M3b), a transistor M4a (M4b), a capacitor C2a (C2b), a resistor R2a (R2b), a resistor R3a (R3b), a current source I1a (I1b), a transistor M5a (M5b), a transistor M6a (M6b), and an inductor L1a (L1b). The transistor M5a (M5b) is the main transistor of the sub-PAD 410 (the PA 232_7), dominating the gain of the sub-PAD 410 (the PA 232_7).

The gate of the transistor M3a (M3b) is coupled or electrically connected to the gate of the transistor M2. The source of the transistor M3a (M3b) is coupled or electrically connected to the voltage VDD. The drain of the transistor M3a (M3b) is coupled or electrically connected to the drain of the transistor M4a (M4b).

The gate of the transistor M4a (M4b) is coupled or electrically connected to the drain of the transistor M4a (M4b). The source of the transistor M4a (M4b) is coupled or electrically connected to the ground voltage GND.

The source of the transistor M5a (M5b) is coupled or electrically connected to the ground voltage GND. The gate of the transistor M5a (M5b) is coupled to the gate of the transistor M4a (M4b) through the resistor R2a (R2b). The drain of the transistor M5a (M5b) is coupled to the inductor L1a (L1b) through the transistor M6a (M6b).

One terminal of the capacitor C2a is coupled or electrically connected to the gate of the transistor M5a; the other terminal of the capacitor C2a receives the input signal PAD_in (e.g., the reference signal Rf_tx2). Similarly, one terminal of the capacitor C2b is coupled or electrically connected to the gate of the transistor M5b; the other terminal of the capacitor C2b receives the input signal PA_in (i.e., the output signal PAD_out of the sub-PAD 410).

The source of the transistor M6a (M6b) is coupled or electrically connected to the drain of the transistor M5a (M5b). The drain of the transistor M6a (M6b) is coupled or electrically connected to the inductor L1a (L1b).

The first terminal of the inductor L1a (L1b) is coupled or electrically connected to the drain of the transistor M6a (M6b); the second terminal of the inductor L1a (L1b) is coupled or electrically connected to the voltage VDD.

One terminal of the current source I1a (I1b) is coupled or electrically connected to the voltage VDD; the other terminal of the current source I1a (I1b) is coupled or electrically connected to the gate of the transistor M6a (M6b).

One terminal of the resistor R3a (R3b) is coupled or electrically connected to the ground voltage GND; the other terminal of the resistor R3a (R3b) is coupled or electrically connected to the gate of the transistor M6a (M6b).

The transistor M2 is connected in series with the current source 610 between a reference voltage (e.g., the voltage VDD) and another reference voltage (e.g., the ground voltage GND). The current source 610 is a current digital-to-analog converter (IDAC). The current of the current source 610 (i.e., the current Idac flowing through the transistor M2) is controlled by the control code D_ramp.

Reference is made to both FIG. 5 and FIG. 6. In some embodiments, the current source 610 may be one of the DAC 236_1 and the DAC 236_3, and the current Idac can correspond to the regulation signal Ctrl_ramp in FIG. 5.

Reference is made to FIG. 6. Because the transistor M3a (M3b) and the transistor M2 form a current mirror, the current flowing through the transistor M4a (M4b) is also controlled by the control code D_ramp, making the voltage TPM_PAD_Vg (PA_Vg) proportional to the current Idac. That is to say, the gate bias of the main transistor M5a (M5b) changes with the control code D_ramp, and the change trend is similar to or substantially the same as the change trend of the current Idac. Due to the gain of the transistor M5a (M5b) being related to the gate bias, the digital baseband circuit 212 can control the output power of the sub-PAD 410 (the PA 232_7) through the control code D_ramp.

The transistor M6a (M6b) is coupled to the transistor M5a (M5b) and is used for enhancing the overall gain of the sub-PAD 410 (the PA 232_7). The current source I1a (I1b) and the resistor R3a (R3b) are used to bias the transistor M6a (M6b). The drain of the transistor M6a (M6b) is coupled to the voltage VDD through the inductor L1a (L1b). The drain of the transistor M6a and the drain of the transistor M6b are the output terminal of the sub-PAD 410 and the PA 232_7, respectively. The inductor L1a and the inductor L1b are respectively the load of the sub-PAD 410 and the PA 232 7. The PA 232_7 outputs the output signal PA_out (corresponding to the RF output signal STx in FIG. 5) through the drain of the transistor M6b.

In summary, because the digital baseband circuit 212 can generate precise control codes D_ramp, the digital baseband circuit 212 can accurately perform the transmitter power ramping, enhancing the flexibility of the transmitter power ramping.

In some embodiments, the transistor M6a, the current source I1a, the resistor R3a, the transistor M6b, the current source I1b, and the resistor R3b can be omitted. As a result, the first terminal of the inductor L1a (L1b) is coupled or electrically connected to the drain of the transistor M5a (M5b), and the drain of the transistor M5a (M5b) becomes the output terminal of the sub-PAD 410 (the PA 232_7).

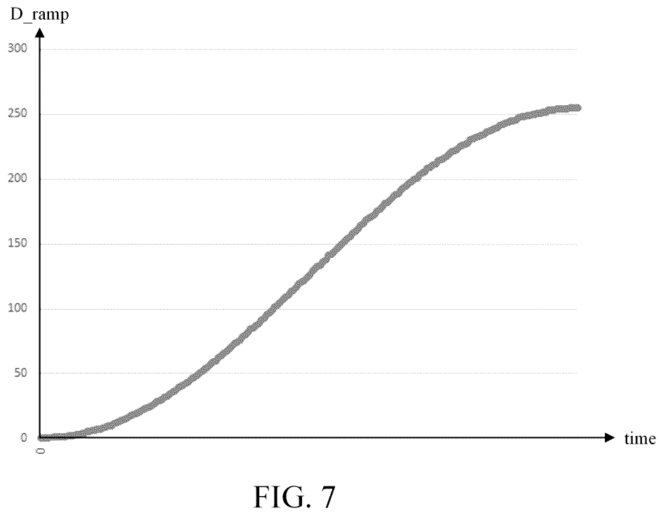

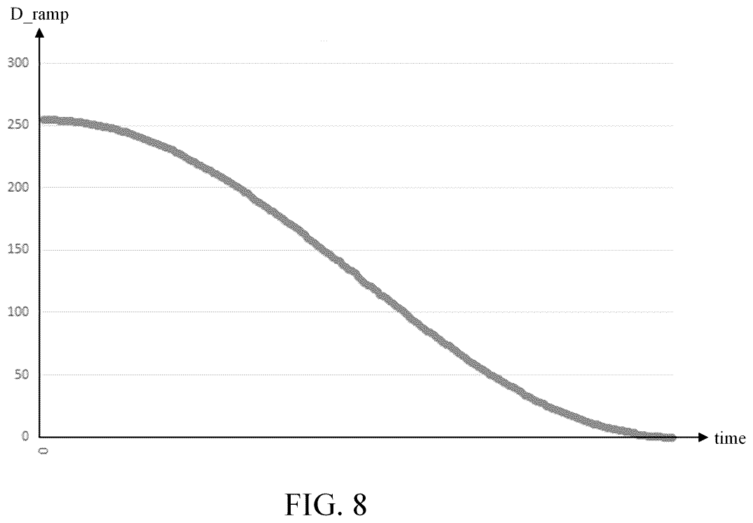

Reference is made to FIG. 7 and FIG. 8, which are schematic diagrams of the control code D_ramp according to an embodiment of the present invention. FIG. 7 corresponds to the RF power ramp-up control, while FIG. 8 corresponds to the RF power ramp-down control. In the examples of FIG. 7 and FIG. 8, the control code D_ramp is 8 bits. As shown in FIG. 7, the digital baseband circuit 212 controls the control code D_ramp to gradually increase from the minimum value (0) to the maximum value (255) within the specified time, generating the curve of the RF power ramp-up control in FIG. 7. As shown in FIG. 8, the digital baseband circuit 212 controls the control code D_ramp to gradually decrease from the maximum value to the minimum value within the specified time, generating the curve of the RF power ramp-up control in FIG. 8.

It should be noted that the change in the current Idac, the voltage TPM_PAD_Vg, and the voltage PA_Vg with respect to time is approximately or substantially equal to the curve in FIG. 7 or FIG. 8.

In summary, the communication chip 201 of the present invention can not only simultaneously support the IQM mode and the TPM mode, but it also uses the DAC 236 of the IQM mode to implement the transmitter power ramping in the TPM mode. In other words, the IQM mode and the TPM mode further share the DAC 236. Therefore, the communication chip 201 of the present invention, in addition to saving circuit area and cost, can also perform the transmitter power ramping more flexibly in the TPM mode, making it easier for the communication chip 201 and the electronic device 200 to comply with various RF power regulations.

It should be noted that the purpose of enhancing the flexibility of transmitter power ramping can be achieved by performing the transmitter power ramping on at least one of the sub-PAD 410 and the PA 232_7.

The TPM and the IQM are intended to illustrate the invention by way of example and not to limit the scope of the claimed invention. People having ordinary skill in the art may apply the present invention to other types of modulation schemes in accordance with the foregoing discussions.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A communication chip, comprising:
a digital baseband circuit configured to generate a control signal and a control code;
a reference signal generation circuit coupled to the digital baseband circuit and configured to generate a reference signal and change a frequency of the reference signal according to the control signal;
a power amplifier driver (PAD) coupled to the reference signal generation circuit;
a power amplifier (PA) coupled to the PAD; and
a digital-to-analog converter (DAC) coupled to the digital baseband circuit and configured to control at least one output power of at least one of the PAD and the PA according to the control code;
wherein the PAD and the PA amplify the reference signal, and the control signal is not equal to the control code.

2. The communication chip of claim 1, wherein the digital baseband circuit further generates a digital output signal, the DAC is configured to convert the digital output signal into an analog output signal, the communication chip transmits a radio frequency (RF) output signal, and the communication chip further comprises:
a filter circuit coupled to the DAC and configured to filter the analog output signal to generate a filtered analog output signal; and
a transmitter front-end circuit coupled to the filter circuit and configured to up- convert and amplify the filtered analog output signal according to the reference signal to generate the RF output signal;
wherein the PAD and the PA are parts of the transmitter front-end circuit.

3. The communication chip of claim 2 further comprising:
an impedance matching circuit coupled to the transmitter front-end circuit;
a pin coupled to the impedance matching circuit; and
a receiver circuit coupled to the impedance matching circuit and configured to receive an RF input signal through the pin and the impedance matching circuit;
wherein the transmitter front-end circuit transmits the RF output signal through the impedance matching circuit and the pin.

4. The communication chip of claim 1, wherein the communication chip further comprises a first transistor coupled to the DAC, and the PAD or the PA comprises:
a load;
a resistor;
a second transistor coupled to the first transistor and forming a current mirror with the first transistor;
a third transistor coupled to the second transistor and having a first gate, a first source, and a first drain, wherein the first drain is coupled to the second transistor, and the first source is coupled to a first reference voltage;
a fourth transistor having a second gate, a second source, and a second drain, wherein the second source is coupled to the first reference voltage, the second drain is coupled to a second reference voltage through the load, and the second gate is coupled to the first gate through the resistor; and
a capacitor having a first terminal and a second terminal, wherein the first terminal is coupled to the second gate, and the second terminal receives a signal.

5. The communication chip of claim 4, wherein the resistor is a first resistor, and the PAD or the PA comprises:
a fifth transistor having a third gate, a third source, and a third drain, wherein the third source is coupled to the second drain, and the third drain is coupled to the load;
a current source coupled between the second reference voltage and the third gate; and
a second resistor coupled between the first reference voltage and the third gate.

6. The communication chip of claim 4, wherein the first gate is electrically connected to the first drain.

7. An electronic device configured to transmit a radio frequency (RF) output signal or receive an RF input signal, comprising:
an antenna; and
a communication chip, comprising:
a digital baseband circuit configured to generate a control signal and a control code;
a reference signal generation circuit coupled to the digital baseband circuit and configured to generate a reference signal and change a frequency of the reference signal according to the control signal;
a power amplifier driver (PAD) coupled to the reference signal generation circuit;
a power amplifier (PA) coupled to the PAD; and
a digital-to-analog converter (DAC) coupled to the digital baseband circuit and configured to control at least one output power of at least one of the PAD and the PA according to the control code;
wherein the PAD and the PA amplify the reference signal, and the control signal is not equal to the control code.

8. The electronic device of claim 7, wherein the communication chip further comprises:
a pin coupled to the antenna; and
an impedance matching circuit coupled to the pin;
wherein the communication chip transmits the RF output signal through the pin and the impedance matching circuit, or receives the RF input signal through the pin and the impedance matching circuit.

9. The electronic device of claim 7, wherein the digital baseband circuit further generates a digital output signal, the DAC is configured to convert the digital output signal into an analog output signal, and the communication chip further comprises:
a filter circuit coupled to the DAC and configured to filter the analog output signal to generate a filtered analog output signal; and
a transmitter front-end circuit coupled to the filter circuit and configured to up- convert and amplify the filtered analog output signal according to the reference signal to generate the RF output signal;
wherein the PAD and the PA are parts of the transmitter front-end circuit.

10. The electronic device of claim 7, wherein the communication chip further comprises a first transistor coupled to the DAC, and the PAD or the PA comprises:
a load;
a resistor;
a second transistor coupled to the first transistor and forming a current mirror with the first transistor;
a third transistor coupled to the second transistor and having a first gate, a first source, and a first drain, wherein the first drain is coupled to the second transistor, and the first source is coupled to a first reference voltage;
a fourth transistor having a second gate, a second source, and a second drain, wherein the second source is coupled to the first reference voltage, the second drain is coupled to a second reference voltage through the load, and the second gate is coupled to the first gate through the resistor; and
a capacitor having a first terminal and a second terminal, wherein the first terminal is coupled to the second gate, and the second terminal receives a signal.

11. The electronic device of claim 10, wherein the resistor is a first resistor, and the PAD or the PA comprises:
a fifth transistor having a third gate, a third source, and a third drain, wherein the third source is coupled to the second drain, and the third drain is coupled to the load;
a current source coupled between the second reference voltage and the third gate; and
a second resistor coupled between the first reference voltage and the third gate.

12. The electronic device of claim 10, wherein the first gate is electrically connected to the first drain.
